(19) United States
(12) Patent Application Publication
(10) Pub. No.: US 2006/0071273 A1
(43) Pub. Date: Apr. 6, 2006

(54) Semiconductor device including an LDMOS transistor

(75) Inventor: Fujii Hiroki, Kawasaki (JP)

Correspondence Address: YOUNG & THOMPSON, 745 SOUTH 23RD STREET, 2ND FLOOR, ARLINGTON, VA, 22202, US

(73) Assignee: HIROKI FUJI, KAWASAKI (JP)

(21) Appl. No.: 11/222,111

(22) Filed: Sep. 9, 2005

(30) Foreign Application Priority Data
Oct. 1, 2004 (JP) 2004-289660

(51) Int. Cl. H01L 29/76

(52) U.S. Cl. 257/343

(57) ABSTRACT

A semiconductor device 100 includes an LDMOS transistor which includes: a P-type silicon substrate 102; a gate electrode 120 formed on the P-type silicon substrate 102; a drain (a second N-type diffusion area 109) formed apart from the gate electrode 120 in the horizontal direction; a drain electrode 130 formed on the drain (the second N-type diffusion area 109); an insulating film (a field oxide film 106) which is provided between the gate electrode 120 and the drain electrode 130, and has a film thickness thicker than that of a gate insulating film 112; and an electric field control electrode 118 formed along the drain electrode 130 on the insulating film.

This application is based on Japanese Patent application NO. 2004-289660, the content of which is incorporated hereinto by reference.

### BACKGROUND OF THE INVENTION

1. Field of the Invention

The present invention relates to a semiconductor device including an LDMOS transistor, and, more particularly, to a semiconductor device including a high-breakdown-voltage LDMOS transistor.

2. Related art

When a lateral diffused metal oxide semiconductor (LDMOS) transistor is used as a high-breakdown-voltage MOS transistor, a configuration, in which the thickness of a gate oxide film at the drain end is increased, or a field oxide film with a larger thickness than that of the gate oxide film is made existed at the drain end, has been generally applied for reduction in the concentration of electric field between drain and gate electrodes. However, the above configuration has had a problem that the drain resistance is increased, and the on-resistance is made larger (for example, Laid-open patent publication No. 2001-60686).

In the LDMOS transistor, a tradeoff between realization of a high breakdown voltage and that of the reduced on-resistance is required to be considered, and it is difficult to realize the both realization at the same time.

It is disclosed in Laid-open patent publication No. 2-283072, a metal oxide semiconductor field effect transistor (MOSFET) with a configuration, in which a gate electrode has an elliptical shape, and drain diffusion areas are formed in a striped pattern within the elliptical shape to realize a broad channel width in order to increase the current capacity. Here, a drain electrode interconnection is extending outward from the inside of the gate electrode with an elliptical shape, and cross over a PN junction surface. Accordingly, the concentration of electric field in a backgating portion is reduced when a negative voltage is applied to the drain electrode interconnection. However, a charge storage layer is formed on the overlap portion between P-type drain diffusion areas and the drain electrode interconnection by electrostatic induction of positive electric charges, based on a MOS effect. Thereby, there has been a problem that the widened width of the end of the depletion layer in the P-type drain diffusion areas with the overlap portions between the P-type drain diffusion areas and the drain electrode interconnections is narrower than that of the areas with no overlap portions between the P-type drain diffusion areas and the drain electrode interconnections. As the higher drain voltage causes the density to become much more increased by the storage layer on the surface of the P-type drain diffusion areas, a widening rate of the depletion layer is limited more and more, and the density of the equipotential lines becomes higher to cause the concentration of the electric field for rate-determining of the breakdown voltage.

Accordingly, the MOSFET of an off-set gate type disclosed in Laid-open patent publication No. 2-283072 has a configuration in which an electrode for application of a bias potential is inserted between afield oxide film just underneath the drain electrode interconnection and an insulating interlayer thereon. Here, a potential with an opposite sign to that of the drain electrode interconnection is applied to the electrode for application of a bias potential. Thereby, the charge storage layer generated by the potential of the drain electrode interconnection is cancelled or reduced by generation of a charge storage layer generated by the potential of the electrode for application of a bias potential and density changes on the side of the surface can be suppressed. Thereby, the end of the depletion layer just underneath the drain electrode interconnection is in a widened position in a similar manner with that of portions which are not covered with the drain electrode interconnection, and the electric field concentration is reduced to increase the drain breakdown voltage.

As described above, the object of Laid-open patent publication No. 2-283072 is an configuration in which under the influence of the potential applied to the drain electrode interconnection, the charge storage layer generated in the P-type drain diffusion area is reduced, and the end of the depletion layer just underneath the drain electrode interconnection has the same widened position as that of areas not covered with the drain electrode interconnection. Accordingly, the electrode for application of a bias potential is required to be formed just underneath the drain electrode interconnection.

It has been difficult for the conventional configuration to realize a high breakdown voltage and, at the same time, a reduced on-resistance.

### SUMMARY OF THE INVENTION

According to the present invention, there is provided a semiconductor device comprising an LDMOS transistor including: a semiconductor substrate; a gate electrode formed on the semiconductor substrate; a drain formed apart from the gate electrode in the horizontal direction; a drain electrode formed on the drain; an insulating film which has a film thickness thicker than that of a gate insulating film and is provided between the gate electrode and the drain; and an electric field control electrode formed on the insulating film along the drain electrode.

In the semiconductor device of this invention, an area in which the density of equipotential lines with high potentials is high can be shifted to the side of the drain electrode by providing the above electric field control electrode, and by applying to the electric field control electrode a voltage between a voltage applied to the gate electrode and a maximum voltage (a breakdown voltage of the LDMOS transistor) applied to the drain electrode when a voltage is applied to the gate electrode and the drain electrode. Thereby, concentration of the electric field at the points of contact between the gate electrode and the end of the insulating film can be reduced, wherein breakdown is easily caused at the above point of contact, and the breakdown voltage of the LDMOS transistor can be increased.

Moreover, an electron/hole storage layer can be formed in the lower portion of the insulating film by applying the above-described voltage to the electric field control electrode at the time of voltage application to the gate electrode and the drain electrode, and the on-resistance of the LDMOS transistor can be reduced.

According to the invention, an LDMOS transistor with a high breakdown voltage, and, at the same time, with a reduced on-resistance can be obtained.

### BRIEF DESCRIPTION OF THE DRAWINGS

The above and other objects, advantages and features of the present invention will be more apparent from the following description taken in conjunction with the accompanying drawings, in which:

FIG. 1A shows a cross-sectional view of a semiconductor device according to an embodiment of the present invention;

FIG. 1B shows a top view of the semiconductor device according to the embodiment;

FIG. 2A is a cross-sectional view showing a step in one example of manufacturing procedures for the semiconductor device;

FIG. 2B is a cross-sectional view showing a step in one example of the manufacturing procedures for the semiconductor device;

FIG. 2C is a cross-sectional view showing a step in one example of the manufacturing procedures for the semiconductor device;

FIG. 3A is a cross-sectional view showing a step in one example of the manufacturing procedures for the semiconductor device;

FIG. 3B is a cross-sectional view showing a step in one example of the manufacturing procedures for the semiconductor device;

FIG. 3C is a cross-sectional view showing a step in one example of the manufacturing procedures for the semiconductor device;

FIG. 4 is a cross-sectional view showing a configuration of a semiconductor device without an electric field control electrode;

FIG. 5A is a view showing an electric field distribution when a voltage is applied to the semiconductor device shown in FIG. 1A and FIG. 1B;

FIG. 5B is a view showing an electric field distribution when a voltage is applied to the semiconductor device shown in FIG. 4;

FIG. 6 is a view showing current values when voltages are applied to the semiconductor device shown in FIG. 1A and FIG. 1B, and the semiconductor device shown in FIG. 4, respectively;

FIG. 7A is an enlarged view showing the electric field distribution at the point A shown in FIG. 5A;

FIG. 7B is an enlarged view showing the electric field distribution at the point A shown in FIG. 5B;

FIG. 8A is a view showing the electric field distribution in the semiconductor device shown in FIG. 1A and FIG. 1B;

FIG. 8B is a view showing that of the semiconductor device shown in FIG. 4;

FIG. 9 is a view showing relations between densities of electrons and depths at each location indicated by arrows in FIG. 8A and FIG. 8B;

FIG. 10 is a view showing the on-resistance of the semiconductor device shown in FIG. 1A and FIG. 1B, and that of the semiconductor device shown in FIG. 4; and

FIG. 11 is a top view showing another example of the semiconductor device in the embodiment.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, an embodiment according to the present invention will be explained, referring to drawings. Here, similar components in all the drawings are denoted by a same reference number and their detailed description will be eliminated as appropriate.

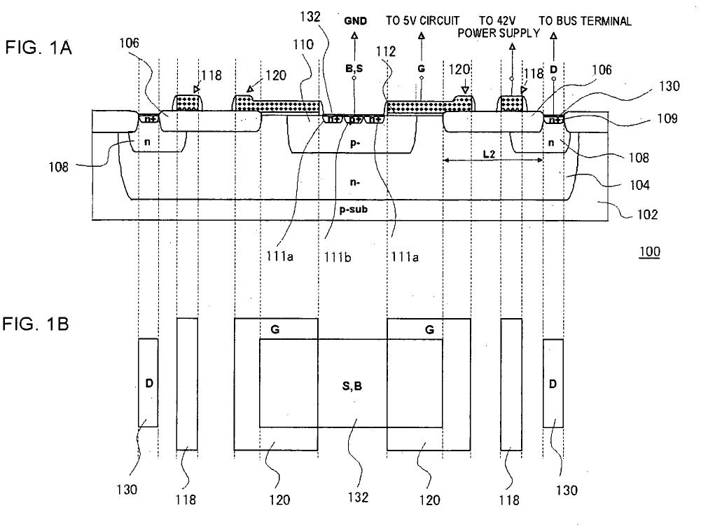

FIG. 1A and FIG. 1B are views showing the configuration of a semiconductor device according to the present embodiment, wherein the device includes an LDMOS transistor.

FIG. 1A shows a cross-sectional view of the semiconductor device 100. Here, the semiconductor device 100 has two symmetrical LDMOS transistors.

The semiconductor device 100 includes: a P-type silicon substrate 102; an N-type well diffusion layer 104 formed on the P-type silicon substrate 102; first N-type diffusion areas 108 formed in the N-type well diffusion layer 104; and, a first P-type diffusion area 110. Moreover, the semiconductor device 100 includes field oxide films 106 each formed between the first P-type diffusion area 110 and the first N-type diffusion areas 108 in the N-type well diffusion layer 104. Above the surfaces of the P-type silicon substrate 102, the semiconductor device 100 further includes gate insulating films 112 formed in such a way that each of the films 112 covers the first P-type diffusion area 110 and each of the field oxide films 106, and gate electrodes 120 each formed on each of the gate insulating films 112, respectively. Moreover, the semiconductor device 100 has second N-type diffusion areas 109 each formed in each of the first N-type diffusion areas 108, drain electrodes 130 each respectively formed on each of the second N-type diffusion areas 109, a third N-type diffusion area 111a and a second P-type diffusion area 111b formed in the first P-type diffusion area 110, and a source electrode 132 formed in such a way that the electrode covers the diffusion areas 111a and 111b.

As the semiconductor device 100 has two symmetrical LDMOS transistors, the description below is made to one of the LDMOS transistors. In the present embodiment, an electric field control electrode 118 is formed on the field oxide film 106 between the gate electrode 120 and the drain electrode 130. The electric field control electrode 118 is provided a part from the gate electrode 120. A voltage controlled in isolation from that applied to the gate electrode 120 is applied to the electric field control electrode 118. In the embodiment, a potential with the same sign as that of the voltage applied to the drain electrode 130 is applied to the electric field control electrode 118. The voltage applied to the electric field control electrode 118 can be assumed to be set between the voltage applied to the gate electrode 120 and the maximum voltage applied to the drain electrode 130. For example, when a working voltage applied to gate electrode 120 is five volts (5V), a voltage applied to the electric field control electrode 118 can be assumed to be set five volts or more and equal to or less than the breakdown voltage of the LDMOS transistor.

The functions of electric field control electrode 118 will be described later in detail. Here, an area in which the density of equipotential lines with high potentials is originally high when a voltage is applied to the gate electrode 120 and the field oxide film 106 can be shifted to the side of the drain electrode 130 by applying a high voltage to the electric field control electrode 118 with the above-described configuration. Therefore, concentration of the electric field at the points of contact between the gate electrode 120 and the field oxide film 106 can be reduced, wherein breakdown is easily caused at the above point of contact, to increase the breakdown voltage of the LDMOS transistor. Moreover, an electron storage layer is formed on the interface between the field oxide film 106 and the N-type well diffusion layer 104 by applying a high voltage to the electric field control electrode 118, to reduce the resistance.

Although, an appropriate position at which the electric field control electrode 118 is arranged depends on a voltage applied to the electric field control electrode 118, the electric field control electrode 118 is preferably formed nearer to the drain electrode 130 than to the gate electrode 120. For example, the electric field control electrode 118 can be formed in the side of the drain electrode 130, between the edge of the drain electrode 130 and the center of the width L2 of the field oxide film 106 in the horizontal direction. Moreover, the electric field control electrode 118 can have a configuration in which the width of the electrode 118 in the horizontal direction is equal to or smaller than half the width of the field oxide film 106. Thereby, the electron storage layer can be locally formed to reduce the on-resistance without reduction in the breakdown voltage of the LDMOS transistor.

Preferably, the electric field control electrode 118 is formed in contact with the field oxide film 106 in order to efficiently perform the above-described functions of the electric field control electrode 118.

FIG. 1B shows a top view of the semiconductor device 100. Only the gate electrodes 120, the drain electrode 130, the source electrode 132, and, the electric field control electrode 118 are arranged in the drawing. As shown in the drawing, the electric field control electrode 118 is continuously formed along the drain electrode 130 in the embodiment. Moreover, the electric field control electrode 118 is arranged between the gate electrode 120 and the drain electrode 130 in such away that the electrode 118 is apart from the both electrodes 120 and 130.

In the embodiment, the gate electrode 120 is connected to, for example, a five-volt circuit, the source electrode 132 is connected to, for example, a ground, and the drain electrode 130 is connected to, for example, a BUS terminal. A voltage controlled in isolation from those, which are applied to the gate electrode 120 and to the drain electrode 130, respectively, is applied to the electric field control electrode 118. FIG. 1A shows an example in which the electrode 118 is connected to a 42-volt power supply. By connecting the electric field control electrode 118 to the power supply to apply a power-supply voltage to a the electrode 118, there is no need to provide a separate or special unit for applying a voltage to the electric field control electrode 118. Accordingly, without having a semiconductor device 100 complicated configuration, an LDMOS transistor with a high breakdown voltage, and, at the same time, with a reduced on-resistance can be obtained.

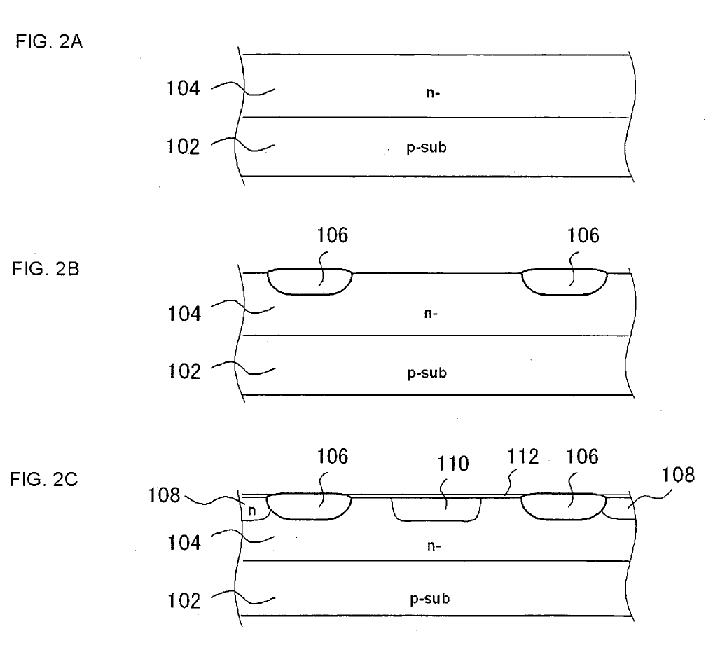

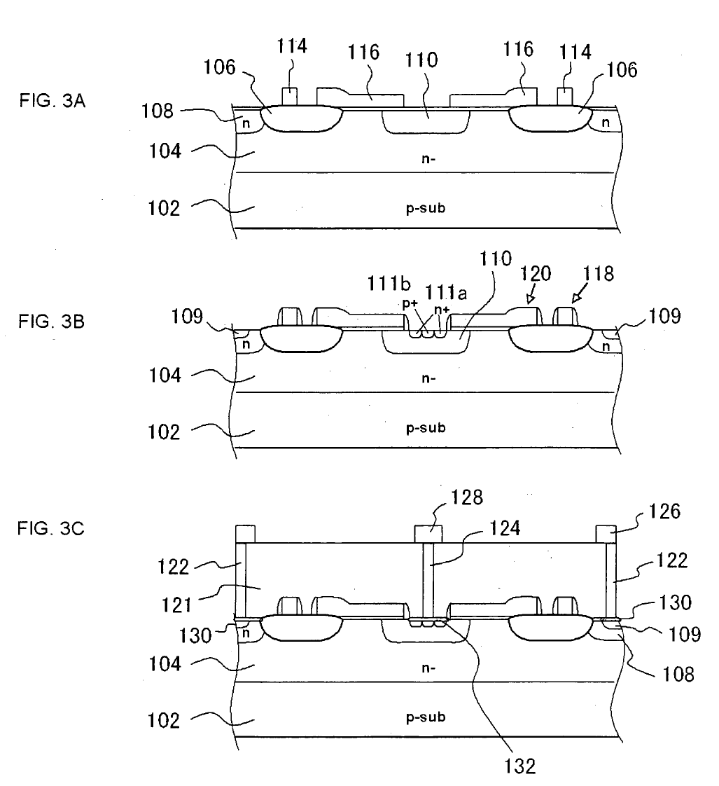

FIG. 2A to FIG. 2C, and FIG. 3A to FIG. 3C are one example of manufacturing procedures for the semiconductor device 100, using cross-sectional views.

Firstly, phosphorus is selectively injected into the P-type silicon substrate 102, using a photoresist, and the N-type well diffusion layer 104 with a depth of about 5 μm to 15 μm is formed by a heat treatment at a high temperature of about 1100° C. (centigrade) to 1200° C. (FIG. 2A). Subsequently, an oxide film, which is formed by the heat treatment at the high temperature, on the surface of the P-type silicon substrate 102 is removed by wet etching. Thereafter, the field oxide film 106 is formed in the N-type well diffusion layer 104 (FIG. 2B).

Thereafter, boron (B) is driven into a position apart from the field oxide film 106 through a thin oxide film with a thickness of several tens nanometers, based on a known photoresist process, to form the first P-type diffusion area 110. Then, the first N-type diffusion area 108 is formed in an area opposite to the area in which the first P-type diffusion area 110 is formed so that the area 108 is in contact with the respective field oxide film 106. The first N-type diffusion area 108 can be formed by implanting phosphorus (P) therein, based on a known photoresist process. Subsequently, the thin oxide film with a thickness of several tens nanometers, which has been remaining on the surface of the P-type silicon substrate 102, is removed by wet etching. Thereafter, the gate insulating film 112 (with a film thickness of about 10 nanometers) is formed (FIG. 2C).

Thereafter, a poly-silicon film (not shown and with a film thickness of about 150 nanometers to 500 nanometers) is formed on the P-type silicon substrate 102. Then, the poly-silicon film is drying etched according to a known photoresist process to form an electric field control poly layer 114 and a gate poly layer 116 (FIG. 3A). According to the method for manufacturing the semiconductor device of the present embodiment, the electric field control poly layer 114 and the gate poly layer 116 can be simultaneously formed, and, without increasing the number of processes, the electric field control electrode 118 capable of providing an LDMOS transistor with a high breakdown voltage, and, at the same time, with a reduced on-resistance can be formed.

Subsequently, an n-LDD area (not shown) is formed by implanting P into the first P-type diffusion area 110, based on a known photoresist process. Thereafter, sidewalls are formed at the electric field control poly layer 114 and the gate poly layer 116 by etch back after forming an oxide film, and the electric field control electrode 118 (a width of about 2 μm to 6 μm in the horizontal direction) and the gate electrode 120 are formed. Then, the third N-type diffusion area 111a as a source is formed on the first P-type diffusion area 110, and the second N-type diffusion area 109 as a drain is formed on the first N-type diffusion area 108 by arsenic (As) implantation according to a known photoresist process. Subsequently, the second P-type diffusion area 111b as a body lead-out section is formed on the first P-type diffusion area 110 by B implantation according to a known photoresist process (FIG. 3B).

Subsequently, the drain electrode 130 is formed on the second N-type diffusion area 109, and the source electrode 132 is formed on the third N-type third diffusion area 111a and the second P-type diffusion area 111b. Here, the drain electrode 130 and the source electrode 132 may be structured by TiSi₂ films. The electric field control electrode 118 and the drain electrode 130 can be formed, for example, about 1 μm apart from each other in the horizontal direction in the drawing. Thereafter, an insulating interlayer 121 is formed all over the P-type silicon substrate 102. The insulating interlayer 121 can be formed by, for example, boro-phospho-silicate glass (BPSG) (boron-phospho-doped oxide film). Then, a contact hole is formed at the insulating interlayer 121 according to a known photoresist process after planarization of the insulating interlayer 121 by chemical-mechanical polishing (CMP). Subsequently, the contact hole is embedded by a conductive material to form a first contact 122 and a second contact 124. Thereafter, a first interconnection 126 connected to the first contact 122, and a second interconnection 128 connected to the second contact 124 are formed (FIG. 3C).

Then, functions of the semiconductor device 100 according to the present embodiment will be explained in comparison with those of a semiconductor device which includes an LDMOS transistor without the electric field control electrode 118.

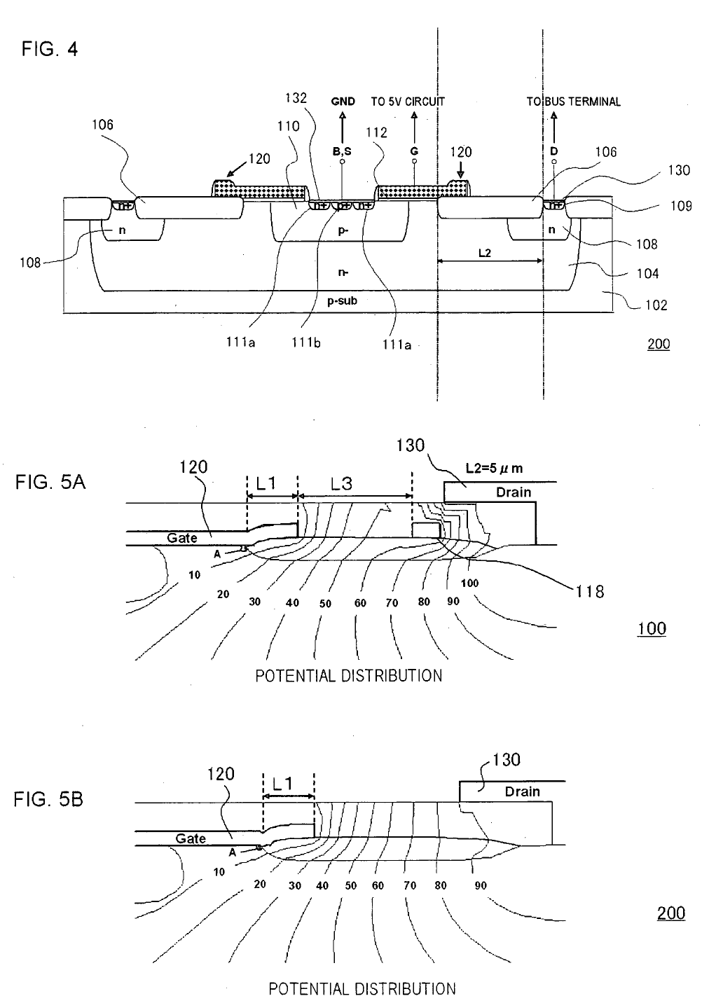

FIG. 4 is a cross-sectional view showing a configuration of a semiconductor device 200 which includes an LDMOS transistor without the electric field control electrode 118. The semiconductor device 200 is different from the semiconductor device 100 according to the present invention in a point that the electric field control electrode 118 (see FIG. 1A and FIG. 1B) is not included. However, a detailed explanation will be hereinafter eliminated because the semiconductor device 200 has a similar configuration to that of the semiconductor device 100 except the above different point.

Firstly, a function by which the off breakdown voltage is increased according to the semiconductor device 100 of the present embodiment will be explained.

FIG. 5A is a view showing an electric field distribution when a voltage is applied to the semiconductor device 100 shown in FIG. 1A and FIG. 1B, and FIG. 5B is a view showing an electric field distribution when a voltage is applied to the semiconductor device 200 shown in FIG. 4.

FIG. 5A shows the electric field distribution in the semiconductor device 100, and FIG. 5B shows the electric field distribution in the semiconductor device 200. Here, a voltage of zero volts is applied to the gate electrode 120, the off breakdown voltage of the LDMOS transistor is applied to the drain electrode 130, and a voltage of 50 volts is applied to the electric field control electrode 118. The width (L2 in FIG. 1A and FIG. 4) of the field oxide film 106 is assumed to be Sum. It is assumed that the width (L1) of the gate electrode 120 overlapping with the field oxide film 106 is 1 μm, the width of the electric field control electrode 118 is 0.6 μm, and the distance (L3) between the end of the gate electrode 120 and the electric field control electrode 118 is 2.5 μm. In any of the cases, the electric field becomes the maximum at a point denoted by A in the drawing to cause a breakdown at each of the above points.

As shown in FIG. 5A, an area in which the density of equipotential lines (where the unit of the numerical value is “V:volt”) with high potentials is high can be shifted to the side of the drain electrode 130 by applying a high voltage to the electric field control electrode 118 according to the semiconductor device 100 of the present embodiment. Thereby, the load of the electric field at the point A can be reduced, and the off breakdown voltage can be more increased in comparison with that of the conventional semiconductor device 200 shown in FIG. 5B.

In the example shown in FIG. 5A, the voltage of 50 volts is applied to the electric field control electrode 118, and the potential line of 50 volts is at the side of the gate electrode 120, and at a short distance from the electric field control electrode 118. Thus, it is preferable for reduction in the load of the electric field at the point A that the electric field control electrode 118 is arranged as near as possible to the drain electrode 130 because an equal potential line of a voltage applied to the electric field control electrode 118 is located at the side of the gate electrode 120, and nearer to the electrode 120 than the electric field control electrode 118. Moreover, it is also preferable to increase a voltage applied to the electric field control electrode 118 to some extent.

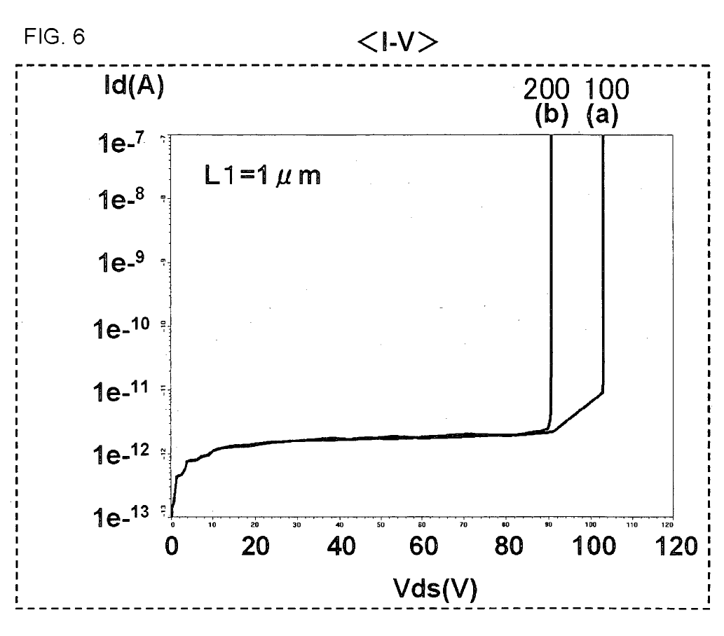

FIG. 6 is a view showing current values when voltages are applied to the semiconductor device 100 shown in FIG. 1A and FIG. 1B, and the semiconductor device 200 shown in FIG. 4, respectively. In this case as well, a voltage of 50 volts was applied to the electric field control electrode 118. In the semiconductor device 200 without the electric field control electrode 118, a breakdown was caused at Vds=about 90 volts. On the other hand, a breakdown occurred at Vds=about 105 volts in the semiconductor device 100 in the present embodiment. Thus, the off breakdown voltage of the semiconductor device 100 can be increased by providing the electric field control electrode 118 between the gate electrode 120 and the drain electrode 130, and by applying a high voltage to the electric field control electrode 118.

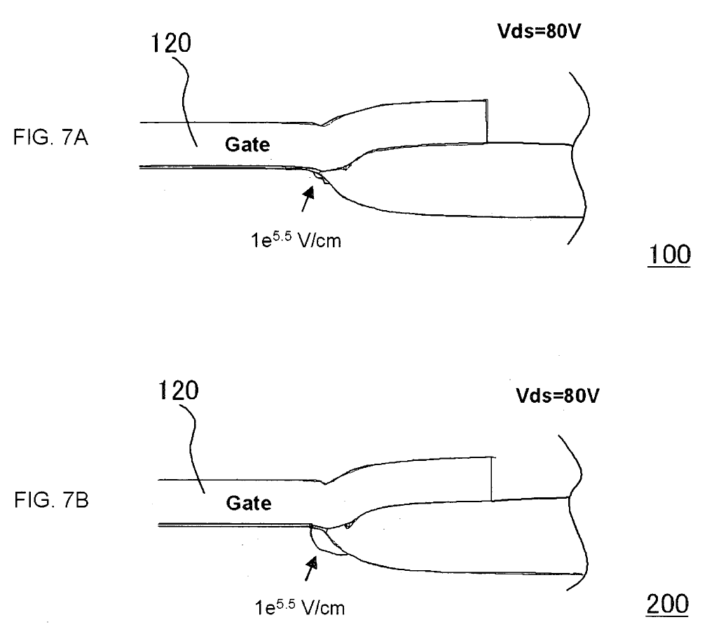

FIG. 7A is an enlarged view showing the electric field distribution at the point A shown in FIG. 5A, and FIG. 7B is an enlarged view showing the electric field distribution at the point A shown in FIG. 5B. Here, a voltage Vds of 80 volts was applied to both of the semiconductor device 100 and the semiconductor device 200. The electric field distributions of 1 e5.5 volts/cm are shown in the drawings. As shown in FIG. 7A, the distribution area for the electric field of 1 e5.5 volts/cm is smaller in the semiconductor device 100 according to the present embodiment in comparison with that, shown in FIG. 7B, in the semiconductor device 200 without the electric field control electrode 118. That is, it is shown, as described above, that the area in which the density of equipotential lines with high potentials is high can be shifted to the side of the drain electrode 130 by applying a high voltage to the electric field control electrode 118, and concentration of the electric field at the point A can be reduced

Thereby, the breakdown voltage of the LDMOS transistor can be increased according to the semiconductor device 100 of the embodiment. The reason is considered to be that, as the area in which the density of equipotential lines with high potentials is high is shifted to the side of the drain electrode 130, the electric field concentration at the gate electrode 120 is reduced to reduce the occurrence of a breakdown.

Subsequently, a function by which the on-resistance is reduced according to the semiconductor device 100 of the embodiment will be explained.

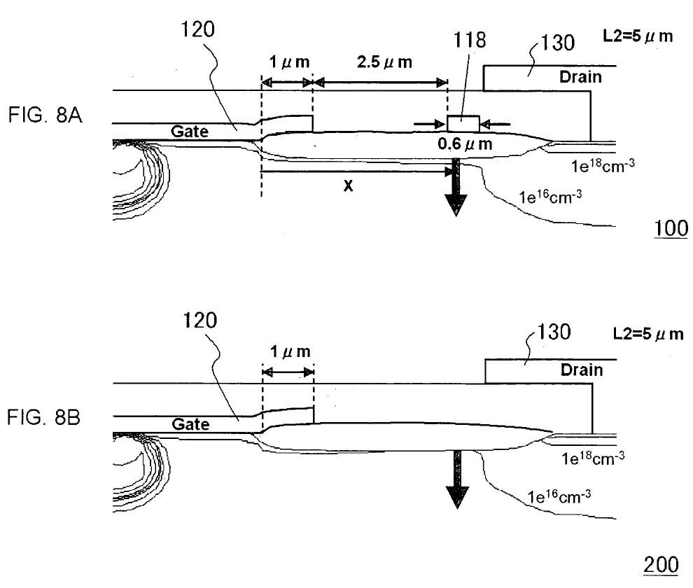

FIG. 8A is a view showing an electric field distribution when a voltage is applied to the semiconductor device 100 shown in FIG. 1A, and FIG. 8B is a view showing an electric field distribution when a voltage is applied to the semiconductor device 200 shown in FIG. 4.

FIG. 8A is a view showing the electric field distribution in the semiconductor device 100, and FIG. 8B is a view showing that of the semiconductor device 200. Here, the gate electrode 120 is connected to the five-volt circuit, and the voltage of about 50 volts is applied to the electric field control electrode 118.

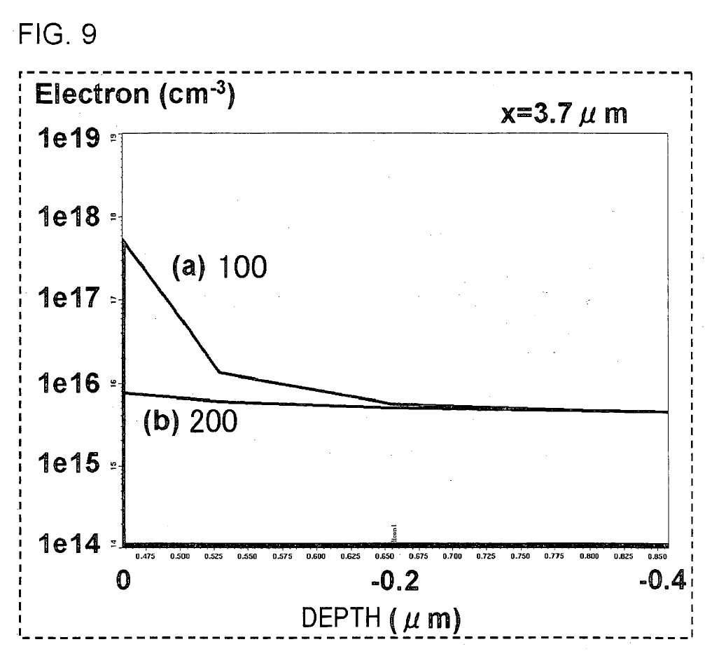

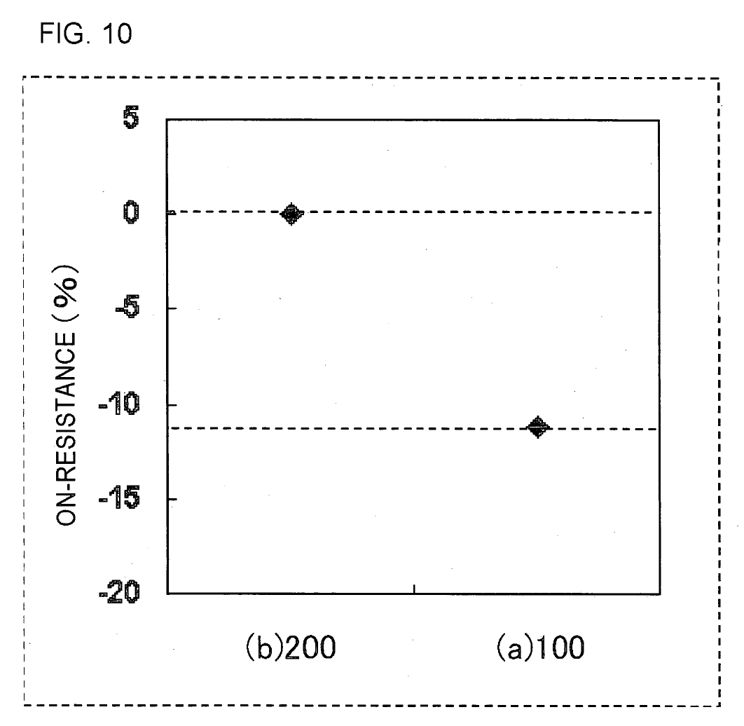

FIG. 9 is a view showing relations between densities of electrons and depths at each location indicated by arrows in FIG. 8A and FIG. 8B.

The density of electrons at locations including a location with a depth of 0 μm is about 1×10¹⁶ cm⁻³ in the semiconductor device 200. The density of electrons is about 1×10¹⁶ cm⁻³ at a location with a depth of − (minus) 0.2 μm in a similar manner to that of the semiconductor device 200 in the semiconductor device 100. However, as for the semiconductor device 100, the density of electrons becomes higher as the depth of the location reaches to the interface between the field oxide film 106 and the N-type well diffusion layer 104, and the density of electrons is about 1×10¹⁸ cm⁻³ at a location with a depth of 0 μm (on the interface between the field oxide film 106 and the N-type well diffusion layer 104). In the semiconductor device 100 according to the embodiment, it is considered that, as a high voltage of about 50 volts is applied to the electric field control electrode 118, electrons cohere on the interface between the field oxide film 106 and the N-type well diffusion layer 104 to increase the density of electrons on the interface.

FIG. 10 is a view showing the on-resistance of the semiconductor device 100 and that of the semiconductor device 200. The drawing shows the on-resistance of the semiconductor device 100 to that of the semiconductor device 200, assuming that the on-resistance (ARon) of the semiconductor device 200 is a standard value (0%). Accordingly, it is found that the on-resistance of the semiconductor device 100 was reduced by about 11.2% in comparison with that of the on-resistance of the semiconductor device 200. The reason is considered to be that the resistance can be reduced because a comparatively thick electron storage layer with a high density of electrons can been formed near on the interface between the field oxide film 106 and the N-type well diffusion layer 104.

As described above, the breakdown voltage of the LDMOS transistor can be increased according to the semiconductor device 100 of the embodiment. Moreover, the on-resistance of the LDMOS transistor can be reduced according to the semiconductor device 100 of the embodiment.

Though embodiments and examples according to the present invention have been described above, referring to the drawings, the present embodiments and the present examples are to be considered as illustrative, and various kinds of configurations, other than the above-described ones, can be applied.

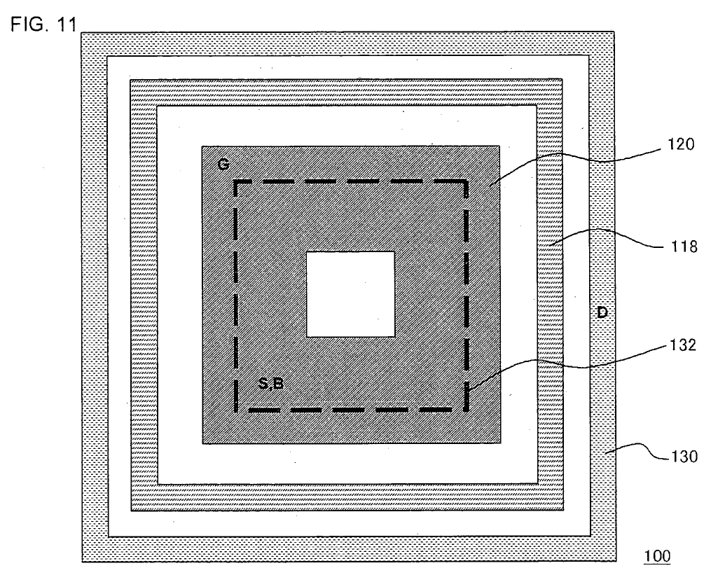

FIG. 1A and FIG. 1B shown the configuration in which the gate electrode 120 and the drain electrode 130 (drain: the second N-type diffusion area 109) are extending in a striped pattern, and the electric field control electrode 118 is formed along the second N-type diffusion area 109 therebetween. The semiconductor device according to the present invention is not limited to the above configuration, but can be applied to LDMOS transistors with various kinds of configurations. FIG. 11 is a view showing another example of the semiconductor device 100. Here, a drain electrode 130 is formed in such a way that the electrode 130 surrounds all sides of a gate electrode 120. An electric field control electrode 118 is formed along the drain electrode 130 in such a way that the electrode 118 continuously surrounds all sides of the gate electrode 120. This invention can be applied to such a semiconductor device 100.

Though the above embodiments have illustrated the configuration in which the electric field control electrode 118 is formed on the field oxide film 106, the present invention is not limited to the above configuration, but can adopt another configuration in which the electric field control electrode 118 is not formed on the field oxide film 106, but an insulating film with a film thickness thicker than that of the gate insulating film 112 is formed on the N-type well diffusion layer 104, and the electric field control electrode 118 is formed thereon.

It is apparent that the present invention is not limited to the above embodiment, which may be modified and changed without departing from the scope and spirit of the invention.

What is claimed is:

1. A semiconductor device comprising an LDMOS transistor including:
a semiconductor substrate;
a gate electrode formed on said semiconductor substrate;
a drain formed apart from said gate electrode in the horizontal direction;
a drain electrode formed on said drain;
an insulating film which has a film thickness thicker than that of a gate insulating film and is provided between said gate electrode and said drain; and
an electric field control electrode formed on said insulating film along said drain electrode.

2. The semiconductor device according to claim 1, wherein said electric field control electrode is structured such that a potential with the same sign as that of a voltage applied to said drain electrode is applied to said electric field control electrode.

3. The semiconductor device according to claim 1, wherein said electric field control electrode is structured such that a power-supply voltage is applied to said electric field control electrode.

4. The semiconductor device according to claim 2, wherein said electric field control electrode is structured such that a power-supply voltage is applied to said electric field control electrode.

5. The semiconductor device according to claim 1, wherein said electric field control electrode has a width equal to or smaller than half the width of said insulating film in the horizontal direction.

6. The semiconductor device according to claim 2, wherein said electric field control electrode has a width equal to or smaller than half the width of said insulating film in the horizontal direction.

7. The semiconductor device according to claim 3, wherein said electric field control electrode has a width equal to or smaller than half the width of said insulating film in the horizontal direction.

8. The semiconductor device according to claim 1, wherein said electric field control electrode is formed nearer to said drain electrode than to said gate electrode in said horizontal direction.

9. The semiconductor device according to claim 2, wherein said electric field control electrode is formed nearer to said drain electrode than to said gate electrode in said horizontal direction.

10. The semiconductor device according to claim 3, wherein said electric field control electrode is formed nearer to said drain electrode than to said gate electrode in said horizontal direction.

11. The semiconductor device according to claim 5, wherein said electric field control electrode is formed nearer to said drain electrode than to said gate electrode in said horizontal direction.
